(19) United States
(12) Patent Application Publication
(10) Pub. No.: US 2011/0236127 A1
(43) Pub. Date: Sep. 29, 2011

(54) STRUCTURE FOR FASTENING RESIN PART

(76) Inventor: Hideyuki Hirota, Tokyo (JP)

(21) Appl. No.: 13/132,944

(22) PCT Filed: Dec. 17, 2009
(86) PCT No.: PCT/JP2009/006976

§ 371 Date: Jun. 6, 2011

(30) Foreign Application Priority Data
Mar. 18, 2009 (JP) 2009-065996 2009

(51) Int. Cl. H05K 7/00; F16B 17/00

(52) U.S. Cl. 403/330

(57) ABSTRACT

A sheet-metal part 8 has engaging hole sections 86 formed in two or more sets, each of which is formed of two holes 86a, 86b, through the right and the left on one side thereof; and resiliently engaging lugs 87a formed by extending downwardly one side of a hole edge of each of cut-raised holes 87 formed at a specific interval on the other side thereof; a resin part 10 has substantially U-shaped resiliently engaging claws 11 for engaging with the engaging holes 86 to be formed at one of opposing opening end edges thereof, and resiliently engaging claws 12 to be extended downwardly so as to be passed through the cut-raised holes 87 formed on the other of the opposing opening end edges thereof and engage with the lower end of the resiliently engaging lugs 87a.

### TECHNICAL FIELD

The present invention relates to a resin part fastening structure for fastening a resin or plastic case to a sheet-metal cover in an electronic apparatus.

### BACKGROUND ART

In the case where a geomagnetic sensor circuit, for example, is incorporated in an electric apparatus mounted on a moving body such as a motor vehicle, a substance generating a magnetic field should not be located around the circuit, and thus the geomagnetic sensor circuit is housed within a resin part. For this reason, when the resin part (case) is mounted to a sheet-metal part (cover), a structure is used in which both of the parts are placed in superposed relation with each other and then secured to each other by screws, or a portion of the resin part is hooked over the sheet-metal part to be fastened by screws. However, there are the following problems: the structure requires screws to increase the number of parts and also the number of screw fastening processes, which leads to a high cost, and also has a poor ability in disassembly, which gives no structure taking recycling into consideration.

On the other hand, Patent Document 1 discloses a structure for holding a built-in battery in a portable apparatus. In the structure, to prevent the built-in battery from being driven out of a battery housing section even if a battery cover is disconnected by shock, a battery hook is slid from a release position to a lock position to press a lock projection, thereby the built-in battery is fixed in the battery housing section, and thereafter the battery cover is assembled to the battery housing section.

### PRIOR ART DOCUMENTS

### Patent Documents

Patent Document 1: JU-A-06-17286 (JU-A-1994-17286)

### SUMMARY OF THE INVENTION

However, although the structure disclosed in Patent Document 1 uses no screws for assembling the battery cover to the battery housing section, no consideration is given to the disassembly of the cover, and thus the structure cannot solve the above problems.

The present invention has been made to solve the above-mentioned problems, and an object of the present invention is to eliminate necessity of screw-fixing in a structure where a resin part is fastened to a sheet-metal part, to thereby facilitate positioning of parts, and improve the abilities of the parts to be assembled and disassembled.

A resin part fastening structure according to the invention includes: a sheet-metal part and a resin part to be assembled to the sheet-metal part, wherein the sheet-metal part has engaging holes in two or more sets, each of which is formed of two holes, through the right and the left on one side thereof; cut-raised holes formed at a specific interval through the other side thereof; and resiliently engaging lugs each formed by extending downwardly one side of a hole edge of each of the cut-raised holes; and wherein the resin part has substantially U-shaped resiliently engaging claws each formed so as to engage with the engaging hole of the sheet-metal part at one of the opposing opening end edges thereof, and resiliently engaging claws each formed so as to be passed through the cut-raised hole and engage with the lower end of the resiliently engaging lug, extending downwardly at the other of the opposing opening end edges thereof.

According to the invention, it is constructed that the substantially U-shaped resiliently engaging claw is engaged in the engaging hole of the sheet-metal part, and also the resiliently engaging claw passed through the cut-raised hole of the sheet-metal part is engaged with the resiliently engaging lug formed by extending downwardly from one side of the edge of the cut-raised hole by resiliently restoring force. Therefore, the resiliently engaging claw has a sufficient length to thereby obtain a large restoring force, and the resin part can be firmly fastened to the sheet-metal part without screws, thus enhancing the ability of the resin part to be assembled thereto.

Further, the substantially U-shaped resiliently engaging claw has a bend section thereof formed in the shape of a circular arc, and thereby the circular arc shaped portion is normally in contact with the edge of a partition section between the holes, thus laterally positioning the parts, facilitating the positioning of the parts, and enabling the parts to be prevented from being displaced.

Moreover, an even number of resiliently engaging claws of the resin part are provided, and the adjacent resiliently engaging claws are arranged to face in opposite directions. Thus, by moving the resiliently engaging claws forming a pair in the direction where the claws are moved toward or away from each other, the engagement of the resiliently engaging claw of the resin part with the resiliently engaging claw of the sheet-metal part can be easily released, and there is obtained an effect that both parts have a great ability to be disassembled and to be recycled.

### BRIEF DESCRIPTION OF THE DRAWINGS

FIG. 1 is a schematic view of an electronic apparatus to which a resin part fastening structure according to the present invention is applied.

FIG. 2 is an exploded perspective view of the electronic apparatus.

FIG. 3 is an exploded perspective view of a cover and a case.

FIG. 4 is an exploded perspective view of the cover and the case of FIG. 3 as is viewed from the opposite direction.

FIG. 5 is a sectional view showing a state where a substantially U-shaped resiliently engaging claw and a partition section between engaging holes are in engagement with each other.

FIG. 6 is a sectional view showing a state where a resiliently engaging claw and a resiliently engaging lug are in engagement with each other.

### BEST MODE FOR CARRYING OUT THE INVENTION

Embodiments of the present invention will now be described with reference to the accompanying drawings in order to explain the present invention in more detail.

### First Embodiment

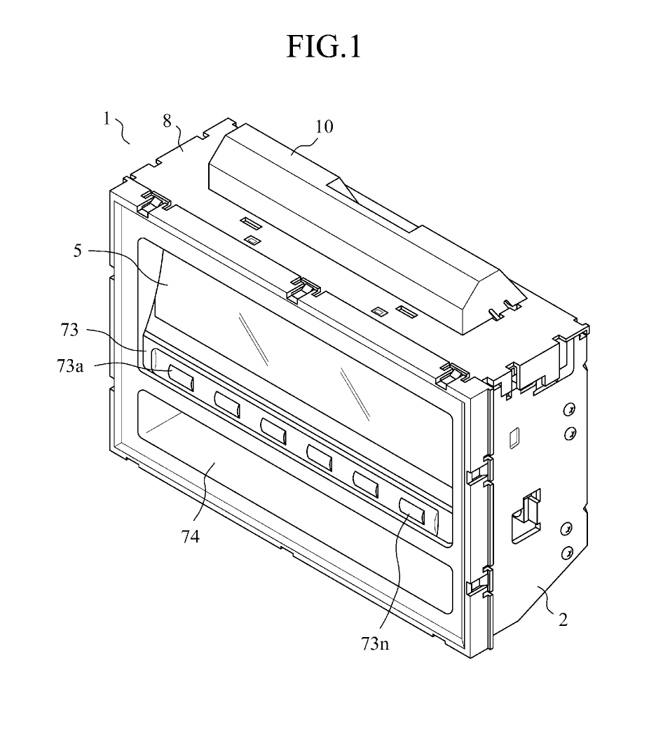

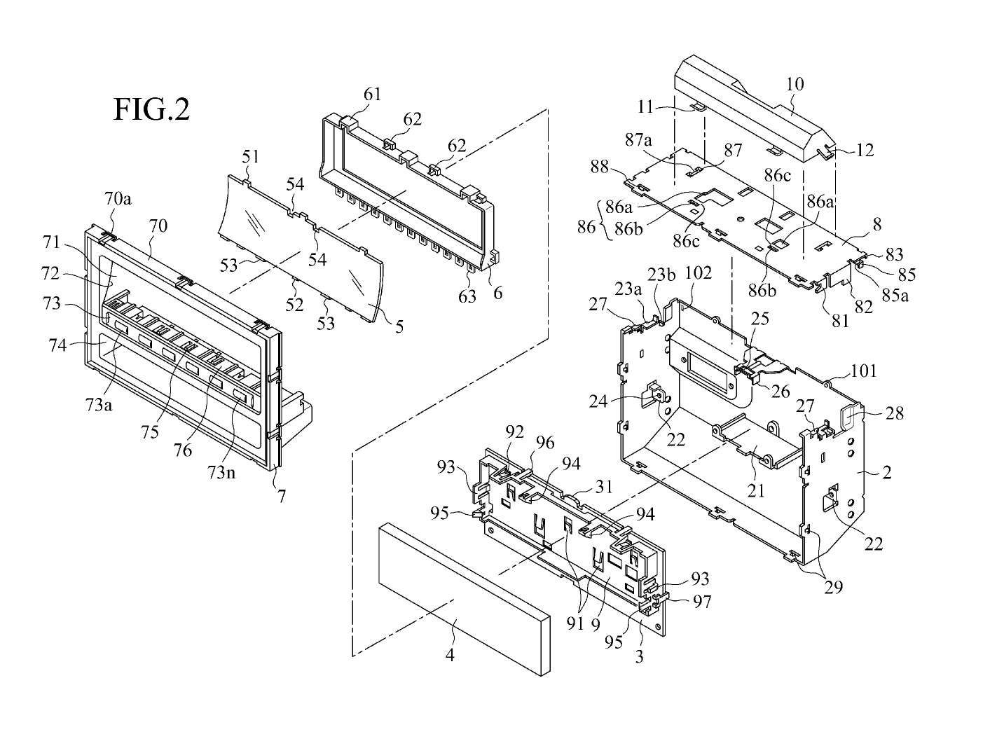

In the following, a resin part fastening structure according to the present invention will be described with reference to the drawings. First, the outline of an electronic apparatus to which a resin part fastening structure according to the present invention is applied will be discussed based on FIG. 1 and FIG. 2. An electronic apparatus 1 includes: a box-shaped and hollow chassis 2; a board 3 to be assembled to the interior of the chassis 2; a display 4 to be assembled to the board 3 through a holder 9; a panel 7 to be assembled to the chassis 2, while a filter 5 disposed opposite the display 4 is attached thereto together with a hood 6; and a cover 8 as a sheet-metal part for covering the opening of the chassis 2, and assembled and fixed to a case 10 as a resin part before or after assembling all of the above parts.

Note that in the following descriptions, expressions of “upper and lower side plates,” “front and back side plates,” and also “right and left side plates” are based on a state where the electronic apparatus 1 is disposed at an in-service position.

The chassis 2 includes: a screw fixing section (also serving as a board receiver) 21 provided in the interior thereof; a first board receiving section 22 that is formed at the same height position as that of the screw fixing section (also serving as a board receiver) 21 by cutting and raising inwardly a portion of each side plate of the chassis 2; board gripping sections 23a, 23b (one of the sections is not shown) that are formed so as to grip the board 3 by cutting and raising inwardly another portion of each side plate of the chassis 2; a board assembling guide section 24 that is formed by folding a portion of the first board receiving section 22 at a substantially right angle toward the board mounting side; and a rectangular opening engaging section 25 formed by turning at a substantially right angle at the upper edge of the back side plate of the chassis 2 so as to engage with a protrusion 31 formed at the edge of the board that is not fixed by screws, and also a second board receiving section 26 that is formed by horizontally extending from each side of the rectangular opening engaging section toward the interior of the chassis and formed at the substantially same height position as those of the screw fixing section (also serving as a board receiver) 21 and the first board receiving section 22.

Further, the chassis 2 is formed of an L-shaped hooking section 27 formed by bending inwardly a portion of a cover mounting opening end of each side plate thereof; an assembly guide section 28 dimpling inwardly the side of the opening end of the chassis 2 by the thickness of the cover 8 in the vicinity of the hooking section 27; and a tapped hole 101 and an engaging hole 102 formed through the upper part of the back side plate thereof.

The display 4 has a rectangular shape with a certain thickness. A holder 9 for holding the display 4 assembled thereto is made of a resin material, and includes: resilient lugs 91 serving as an urging unit in the direction of thickness, and formed on the bottom face by cutting and raising a portion of the bottom face so as to urge the display 4 mounted thereon in the direction of thickness; resilient lugs 92 working as an urging unit in the downward direction, and formed by cutting and raising inwardly a portion of the upper side plate so as to urge the display 4 toward the terminal side; resilient lugs 93 working as a sandwiching unit, and formed by cutting and raising inwardly a portion of each of the right and the left side plates so as to sandwich the display 4 from right and left; and resiliently engaging claws 94 and 95 serving as a surface pressing unit, and formed on the upper side plate, and also the right and the left side plates so as to press the surface of the display 4.

Also, resiliently engaging claws 96 and 97 for assembling and fixing the holder 9 to the board 3 are formed on the back side plate and the right and left side plates of the holder 9 by extending in the direction of thickness. Further, engaging claws for engaging with holes of the board 3 are formed on the bottom face thereof; however, indications thereof is omitted in FIG. 2.

The panel 7 includes an assembling wall 70 relative to the chassis 2 therearound, and has a display window 71 that is formed inside a predetermined distance away from the upper side plate forming the wall 70; a filter mounting section 72 formed in the shape of a frame on the fringe of the display window 71; an operation button housing section 73 for housing a plurality of operation buttons 73a to 73n that are formed along the lower edge of the filter mounting section 72; and a glove compartment 74 that is formed and positioned between the operation button housing section 73 and the lower side plate of the wall 70. The upper and the lower side plates and the right and the left side plates forming the assembling wall 70 are provided with rectangular opening engaging sections 70a for engaging with the engaging claws formed on the chassis 2.

The hood 6 is made of a resin material in the shape of a frame, and has cover sections 61 and engaging holes 62 on the upper frame side plate thereof that is assembled to the outer face of the upper side plate of the filter mounting section 72. Further, the hood 6 has on the lower frame side plate thereof resilient press sections 63 that are formed by projecting at a specific interval so as to abut against the bottom face of the operation buttons, and engaging projections (not shown) for engaging in engaging concavities (omitted in FIG. 2).

The filter 5 is formed with a curved face so as to conform to the filter mounting section 72. At the upper end edge of the filter, there is provided with hooking resiliently engaging claws 51 having a taper and formed at a specific interval so as to engage with rectangular opening engaging sections (omitted in FIG. 2) of the panel 7; and concavities 54 at the positions with which the protrusions (omitted in FIG. 2) formed in the filter mounting section 72 engage, while at the lower end edge thereof, there is provided with engaging claws 52 and positioning convexities 53 formed so as to engage with the resiliently engaging claws 75 and the positioning concavities 76 formed on the outer face of the operation button housing section 73, respectively.

In the cover 8, hooking claws 81 for engaging with the L-shaped hooking sections 27 of the chassis 2; and guide lugs 82 for engaging with the assembly guide sections 28 are formed in the cover 8, with extending from the upper end edge of each side plate of the cover in the assembling direction, and also the cover has a right-angularly bent lug 83 to be superposed on the outer face of the back side plate of the chassis 2; screw passing holes (omitted in FIG. 2) opposed to the tapped holes 101 of the chassis; and engaging claws 85 for engaging with the engaging holes 102. It is preferable to provide a taper 85a on the engaging claw 85 such that the engaging claw easily engages with the engaging hole 102. Further, four corners of the engaging hole 102 are arranged to have a circular arc portion (not shown) and the circular arc portion is normally caused to come in contact with the engaging claw 85.

The engagement faces between the hooking section 27 and the hooking claw 81 are provided with tapers (not shown) such that the chassis 2 and the cover 8 impart a pressing force to each other, and the terminal portions of the tapers are formed in the shape of a circular arc (not shown). Further, the cover 8 includes engaging hole sections 86 formed by juxtaposing two holes 86a, 86b and resiliently engaging lugs formed by extending downwardly one side of the edges of a cut-raised hole 87.

On the other hand, in a case 10 assembled to the cover 8, substantially U-shaped resiliently engaging claws 11 also serving as a positioner to engage with the engaging hole sections 86 of the cover 8; and resiliently engaging claws 12 extending downward so as to pass through the cut-raised hole 87 of the cover 8 and normally engage with the lower end of the engaging lug 87a are formed at the opening end edge of the case 10 to be opposite thereto.

In the following, assembly of the parts will be described. To assemble the display 4 to the holder 9, as the display 4 is pressed to the holder 9 from the top face thereof, the display 4 advances while outwardly pressing and widening the resilient lugs 92, the resilient lugs 93, and the resiliently engaging claws 94 and 95, and further advances while depressing the resilient lugs 91. Further, as the display 4 passes therethrough, the resilient lugs 92 urge the display 4 to a terminal side, the resilient lugs 93 sandwich the display 4 from right and left, and the resiliently engaging claws 94 and 95 press and maintain the face of the display 4 to be forced upwardly by the urging force of the resilient lugs 91, thus completing the assembly of the display 4 to the holder 9. After completing the assembly (the following processes may be performed before the assembly of the display), the holder 9 is assembled to the board 3 with the resiliently engaging claws 96 and 97, and the engaging claws of which indications are omitted, as shown in FIG. 2.

Next, the board 3 having the display 4 assembled thereto is mounted on the first board receiving sections 22 formed on each side plate of the chassis 2 to be moved in the assembling direction and be sandwiched at both side edges thereof by the board gripping sections 23a, 23b. At the movement terminated position, the board 3 is mounted on the second board receiving section 26 at the moving front end thereof, and the protrusion 31 formed at the end edge of the board that is not fixed by screws enters the rectangular opening engaging section 25. In this state, the board 3 is mounted on the screw fixing section (also serving as a board receiver) 21 at the back end side thereof to be fixed by screws.

On the other hand, to assemble the cover 8 to the opening of the upper face of the chassis 2, the guide lug 82 of the cover 8 is moved along the assembly guide section 28 of the chassis 2 to cause the cover 8 to abut against the opening end of the chassis 2, thus preventing the cover 8 drawn too much to the chassis side to be lowered.

Next, the cover 8 is moved until the right-angularly bent lug 83 abuts against the outer face of the back side plate of the chassis 2 in a state where the cover is abutted against the opening end face thereof to thereby engage the hooking section 27 with the hooking claw 8, and then adjust these lateral and vertical positions to be in mesh with each other. In this case, since the hooking section 27 and the hooking claw 81 are formed with a taper such that an entrance thereof widen and a root thereof narrow, the hooking section and the hooking claw are easily combined to each other, and also they can be firmly secured to each other in the combined state. Further, by providing circular arc portions at the roots of the hooking section 27 and the hooking claw 81, respectively, the hooking section 27 and the hooking claw 81 are caused to normally come in contact with each other, thus enabling the two engaging members to be maintained at tension.

Further, as the right-angularly bent lug 83 of the cover 8 is abutted against the outer face of the back side plate of the chassis 2 to be superposed, the engaging claw 85 formed at the right-angularly bent lug 83 engages with the engaging hole 102 of the back side plate of the chassis 2, and thereby the cover 8 is positioned and held to the chassis 2. Therefore, while maintaining this state, a screw (omitted in FIG. 2) passed through the screw passing hole of the right-angularly bent lug 83 is screwed into the tapped hole 101 of the chassis 2 to be screw-fixed. In this case, the engaging claw 85 has the taper, and the four corners of the engaging hole 102 are formed with a circular arc portion. Thus, the engaging claw 85 is easily inserted into the engaging hole 102, the engaging claw 85 is normally in contact with the corner of the circular arc portion of the engaging hole 102, and the back plate of the chassis 2 is gripped between the cover 8 and the engaging claw 85, thus enabling the cover and the chassis to be maintained at tension.

On the other hand, to assemble the filter 5 to the panel 7, as the hooking engaging claw 51 of the filter 5 is first engaged with the rectangular opening engaging section 70a of the panel 7 to press the side of the lower end of the filter against the one of the panel, the resiliently engaging claw 52 engages with the engaging claw 75 on the side of the panel in this process, and also the positioning convexity 53 engages with a positioning concavity (omitted in FIG. 2) on the side of the panel, thus assembling the filter 5 to the panel 7.

After assembling the filter, the peripheral portion of the hood 6 is fitted in an L-shaped drawing positioning section (omitted in FIG. 2) on the side of the panel such that the peripheral portion of the filter is covered, and engaging claws (omitted in FIG. 2) on the side of the panel are engaged with the engaging holes 62. This assembly causes the cover sections 61 to cover rectangular opening engaging sections (omitted in FIG. 2) located on the side of the panel, and the resilient pressing sections 63 abut against the bottom faces of the operation buttons 73a-73n to impart a restoring force to the operation buttons.

The wall 70 of the panel 7, to which the filter 5 and the hood 6 have been thus assembled, is fitted in the front opening of the chassis 2 having the board 3 assembled thereto as discussed above, and cut-raised engaging claws 29 formed on the chassis 2, and cut-raised engaging claws 88 of the cover 8 are engaged with the rectangular opening engaging sections formed on the wall 70, thus completing the assembly of the electronic apparatus 1.

Moreover, before the assembly or after the completion of the assembly as mentioned above, the case 10 is assembled and fixed to the cover 8. In this case, the substantially U-shaped resiliently engaging claws 11 of the case 10 are inserted from the holes 86a located in the upper face of the cover 8, further the case 10 is rotated from this state to the side of the cover 8 to thereby insert the tip portions of the resiliently engaging claws 11 into the holes 86b from the lower face of each of partition sections 86c located between the holes 86a, 86b to thus perform these positionings in a lateral direction, and then the engaging claws 12 are inserted into the cut-raised holes 87 to be engaged with the engaging lugs 87a, thus enabling the case 10 to be firmly assembled to the cover 8 without screws.

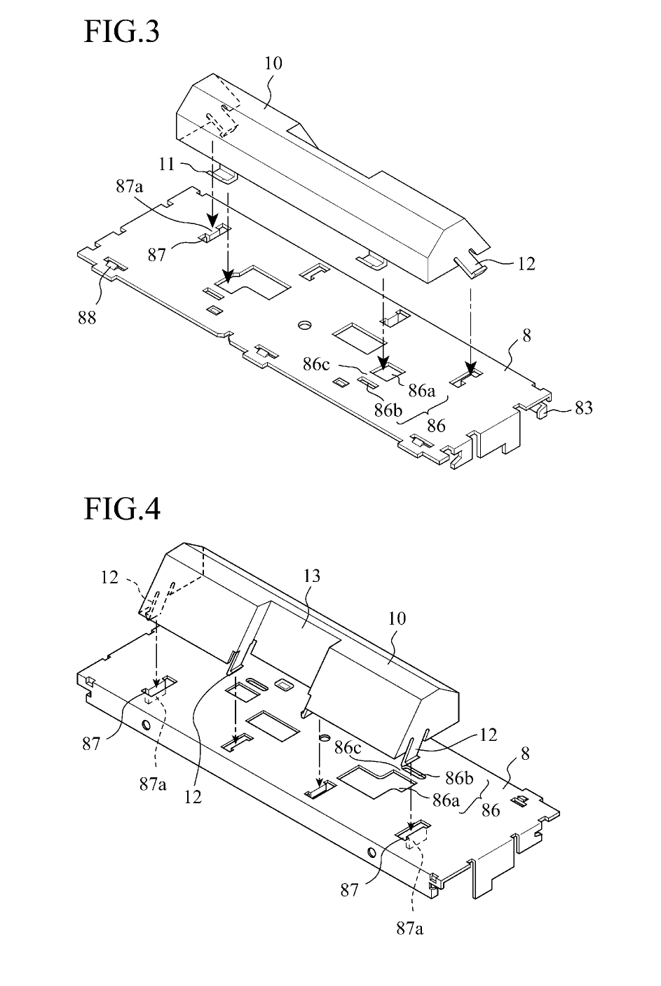

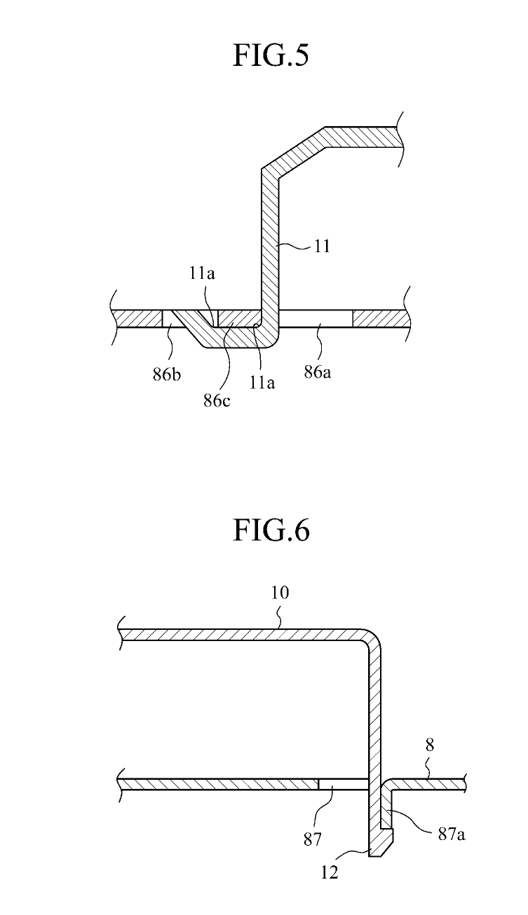

In the electronic apparatus 1 thus arranged, the present invention is contrived such that the case is assembled to the cover without screw-fixing. FIG. 3 is an exploded perspective view of the cover and the case, FIG. 4 is an exploded perspective view of the cover and the case of FIG. 3 as is viewed from the opposite direction, FIG. 5 is a sectional view showing a state where a substantially U-shaped resiliently engaging claw and a partition section between engaging holes are in engagement with each other, and FIG. 6 is a sectional view showing a state where a resiliently engaging claw and a resiliently engaging lug are in engagement with each other.

The cover 8 in the resin part fastening structure according to the present invention has the engaging hole sections 86 formed in two or more sets, each of which is formed of the two holes 86a, 86b, through the right and the left on one side thereof, and also has the cut-raised holes 87 formed at a specific interval on the other side thereof, and the resiliently engaging lugs 87a each formed by extending downwardly one side of a hole edge of each of the cut-raised holes.

The case 10 has substantially U-shaped resiliently engaging claws 11 formed so as to engage with the engaging holes 86a, 86b of the cover 8 at one of the opposing opening end edges thereof, and resiliently engaging claws 12 each formed so as to be passed through the cut-raised hole 87 and engage with the lower end of the resiliently engaging lug 87a, extending downwardly from the other of the opposing opening end edges thereof. Further, the case 10 has the longitudinally intermediate portion thereof recessed to a predetermined width to have a recess 13, and has a resiliently engaging claw 12 formed extending downwardly from each of the opposing sides of the recess thereof, with the adjacent resiliently engaging claws 12 arranged to face in opposite directions. In this case, by arranging that an even number of resiliently engaging claws 12 be provided and the adjacent resiliently engaging claws 12 face in opposite directions, the resiliently engaging claws forming a pair are moved in the direction where the claws are moved toward or away from each other, thus enabling the engagement of the resiliently engaging claws with the engaging claws on the side of the cover to be easily released.

With the above construction, to assemble and fix the case 10 to the cover 8, the substantially U-shaped resiliently engaging claw 11 of the case 10 is inserted into the hole 86a of the cover 8, and then the resiliently engaging claw 11 is come in contact with the edge of the hole, thus completing the laterally positioning of the case. Under such a condition, the case 10 is turned to the side of the cover 8 to insert the resiliently engaging claws 12 into the cut-raised holes 87 to be engaged with the engaging lugs 87a, and also the tip portion of the resiliently engaging claws 11 is inserted into the hole 86b from the lower portion of the partition section 86c located between the holes 86a, 86b to be engaged therewith.

As a result, the circular arc portion 11a located inside the U-shaped bend of the substantially U-shaped resiliently engaging claw 11 comes in contact with the edge of the partition section 86c, thus surely preventing the substantially U-shaped resiliently engaging claw from being dislocated and disconnected from the partition section. Moreover, by increasing the length of the resiliently engaging claw 12 according to the length of the resiliently engaging lug 87a, the ability to be easily bent and sufficient resilience can be given to the resiliently engaging claw, thus enabling the ability of the engaging claw to be smoothly inserted thereinto to be secured. Furthermore, the resiliently restoring force generating between the resiliently engaging claw and the resiliently engaging lug outwardly and inwardly imposes load on each other, thus enabling the engagement thereof to be firmly maintained and thereby enabling the case 10 to be firmly assembled to the cover 8 without screws.

As discussed above, according to the present invention, the substantially U-shaped resiliently engaging claw on the side of the case is engaged with the engaging hole section on the side of the cover, thus facilitating the positioning of the case and enabling the ability of the case and cover to be assembled and disassembled to be improved. Further, by arranging the resiliently engaging lug formed in the sheet-metal cover and the resiliently engaging claw formed in the resin case to have a sufficient length, the resiliently engaging claw moves while being deformed by the contact thereof with the resiliently engaging lug, and when the resiliently engaging claw passes the location of the resiliently engaging lug, the claw is resiliently restored to thereby engage with the lug. Thus, the resiliently engaging lug and the resiliently engaging claw can obtain a large restoring force, thus enabling the case to be firmly secured to the cover without screws.

Furthermore, by arranging the substantially U-shaped resiliently engaging claw to have the circular arc portion at the bend section thereof, the circular arc portion normally comes in contact with the edge of the partition section between the holes, thus laterally positioning the parts, facilitating the positioning thereof, preventing the dislocation thereof, and enabling the state where the parts are stably assembled to each other to be maintained.

Moreover, an even number of substantially U-shaped resiliently engaging claws are provided on the side of the resin case, and the adjacent resiliently engaging claws thereof are arranged to face in opposite directions. Thus, by moving the resiliently engaging claws forming a pair in the direction where the claws are moved toward or away from each other, the engagement of the resiliently engaging claws with the respective engaging claws on the side of the cover can be easily released; thus, there is obtained an advantage effect that has great abilities to be disassembled and also recycled.

### INDUSTRIAL APPLICABILITY

Since the resin part fastening structure according to the present invention has effects including facilitation of positioning of the parts and improvement of the assembly thereof, it is suitable for use in, for example, the case where a resin part is fastened to a sheet-metal cover.

1. A resin part fastening structure comprising a sheet-metal part, and a resin part to be assembled to the sheet-metal part,
wherein the sheet-metal part has engaging holes formed in two or more sets, each of which is formed of two holes, through right and left on one side thereof, and resiliently engaging lugs each formed by extending downwardly one side of a hole edge of each of cut-raised holes formed at a specific interval on the other side thereof, and
wherein the resin part has substantially U-shaped resiliently engaging claws each formed so as to engage with the engaging hole at one of the opposing opening end edges thereof, and resiliently engaging claws each formed so as to be passed through the cut-raised hole and engage with the lower end of the resiliently engaging lug, extending downwardly from the other of the opposing opening end edges thereof.

2. The resin part fastening structure according to claim 1, wherein the substantially U-shaped resiliently engaging claw has the inner portion of a bend section thereof that is formed in the shape of a circular arc.

3. The resin part fastening structure according to claim 1, wherein an even number of the resiliently engaging claws are provided, and the adjacent resiliently engaging claws are arranged so as to face in opposite directions.

4. The resin part fastening structure according to claim 1, wherein the resin part has the longitudinally intermediate portion thereof recessed to a predetermined width, has the resiliently engaging claws each formed by extending downwardly from each of the opposing sides of the recess, and arranges the resiliently engaging claws to face in opposite directions.
